(19) United States
(12) Patent Application Publication
(10) Pub. No.: US 2014/0007928 A1
(43) Pub. Date: Jan. 9, 2014

(54) MULTI-JUNCTION PHOTOVOLTAIC DEVICES

(71) Applicants: Young-June YU, Cranbury, NJ (US); Munib Wober, Topsfield, MA (US)

(72) Inventors: Young-June YU, Cranbury, NJ (US); Munib Wober, Topsfield, MA (US)

(73) Assignee: ZENA TECHNOLOGIES, INC., Cambridge, MA (US)

(21) Appl. No.: 13/543,307

(22) Filed: Jul. 6, 2012

(51) Int. Cl. H01L 31/02; H01L 31/18

(52) U.S. Cl. 136/255; 257/432; 438/72; 257/E31.128; 257/E31.054

(57) ABSTRACT

Described herein is a photovoltaic device operable to convert light to electricity, comprising a substrate, one or more structures essentially perpendicular to the substrate, and a reflective layer disposed on the substrate, and one or more junctions conformally disposed on the one or more structures.

### CROSS-REFERENCE TO RELATED APPLICATIONS

This application is related to U.S. patent application Ser. Nos. 12/621497, 12/633297, 61/266064, 12/982269, 12/966573, 12/967880, 61/357429, 12/974499, 61/360421, 12/910664, 12/945492, 12/966514, 12/966535, 13/047392, 13/048635, 13/106851, 61/488535, 13/288131, 13/494661, and 61/563,279, the disclosures of which are hereby incorporated by reference in their entirety.

### BACKGROUND OF THE INVENTION

A photovoltaic device, also called a solar cell is a solid state device that converts the energy of sunlight directly into electricity by the photovoltaic effect. Assemblies of cells are used to make solar modules, also known as solar panels. The energy generated from these solar modules, referred to as solar power, is an example of solar energy.

The photovoltaic effect is the creation of a voltage (or a corresponding electric current) in a material upon exposure to light. Though the photovoltaic effect is directly related to the photoelectric effect, the two processes are different and should be distinguished. In the photoelectric effect, electrons are ejected from a material's surface upon exposure to radiation of sufficient energy. The photovoltaic effect is different in that the generated electrons are transferred between different bands (i.e. from the valence to conduction bands) within the material, resulting in the buildup of a voltage between two electrodes.

Photovoltaics is a method for generating electric power by using solar cells to convert energy from the sun into electricity. The photovoltaic effect refers to photons of light-packets of solar energy-knocking electrons into a higher state of energy to create electricity. At higher state of energy, the electron is able to escape from its normal position associated with a single atom in the semiconductor to become part of the current in an electrical circuit. These photons contain different amounts of energy that correspond to the different wavelengths of the solar spectrum. When photons strike a PV cell, they may be reflected or absorbed, or they may pass right through. The absorbed photons can generate electricity. The term photovoltaic denotes the unbiased operating mode of a photodiode in which current through the device is entirely due to the light energy. Virtually all photovoltaic devices are some type of photodiode.

### SUMMARY

Described herein is a photovoltaic device operable to convert light to electricity, comprising a substrate, one or more structures essentially perpendicular to the substrate, and a reflective layer disposed on the substrate, and one or more junctions conformally disposed on the one or more structures.

### BRIEF DESCRIPTION OF THE DRAWINGS

FIG. 1A is a schematic cross sectional view of a photovoltaic device according to an embodiment.

FIG. 1B shows details of the device of FIG. 1A.

FIG. 2A is an exemplary process of manufacturing the photovoltaic device of FIG. 1A and 1B, according to an embodiment.

FIG. 2B shows details of some steps in the process in FIG. 2A.

FIG. 3 shows alternative stripe-shaped structures of the photovoltaic device.

FIG. 4 shows alternative mesh-shaped structures of the photovoltaic device.

### DETAILED DESCRIPTION OF THE INVENTION

The term “photovoltaic device” as used herein means a device that can generate electrical power by converting light such as solar radiation into electricity. The term “single-crystal” as used herein means that the crystal lattice of the material is continuous and unbroken throughout the entire structures, with essentially no grain boundaries therein. An electrically conductive material can be a material with essentially zero band gap. The electrical conductivity of an electrically conductive material is generally above 10³ S/cm. A semiconductor can be a material with a finite band gap up to about 3 eV and general has an electrical conductivity in the range of 10³ to 10⁻⁸ S/cm. An electrically insulating material can be a material with a band gap greater than about 3 eV and generally has an electrical conductivity below 10⁻⁸ S/cm. The term “structures essentially perpendicular to the substrate” as used herein means that angles between the structures and the substrate are from 85° to 90°. The term “cladding layer” as used herein means a layer of substance surrounding the structures. The term “continuous” as used herein means having no gaps, holes, or breaks. The term “coupling layer” as used herein means a layer effective to guide light into the structures.

A group III-V compound material as used herein means a compound consisting of a group III element and a group V element. A group III element can be B, Al, Ga, In, Tl, Sc, Y, the lanthanide series of elements and the actinide series of elements. A group V element can be V, Nb, Ta, Db, N, P, As, Sb and Bi. A group II-VI compound material as used herein means a compound consisting of a group II element and a group VI element. A group II element can be Be, Mg, Ca, Sr, Ba and Ra. A group VI element can be Cr, Mo, W, Sg, O, S, Se, Te, and Po. A quaternary material is a compound consisting of four elements.

Described herein is a photovoltaic device operable to convert light to electricity, comprising a substrate, one or more structures essentially perpendicular to the substrate, and a reflective layer disposed on the substrate, and one or more junctions conformally disposed on the one or more structures. The photovoltaic device preferably comprises at least two junctions conformally disposed on the one or more structures.

In an embodiment, the substrate is an electrically insulating material. The substrate can comprise glass, polymer, one or more suitable electrically insulating materials, or a combination thereof.

In an embodiment, the substrate is an electrically conductive material. The substrate can comprise one or more metals, one or more suitable electrically insulating material, one or more other electrically conductive materials, or a combination thereof.

In an embodiment, the substrate is flexible. In an embodiment, the substrate is transparent.

In an embodiment, the substrate has a thickness of about 5 μm to about 300 μm, preferably of about 200 μm.

In an embodiment, the one or more structures essentially perpendicular to the substrate are cylinders or prisms with a cross-section selected from a group consisting of elliptical, circular, rectangular, and polygonal cross-sections, strips. The one or more structures essentially perpendicular to the substrate may be a mesh. The term “mesh” as used herein means a web-like pattern or construction.

In an embodiment, the structures are cylinders with diameters from about 0.2 μm to about 10 μm, preferably with diameters about 1 μm.

In an embodiment, the structures are cylinders or prisms with heights from about 2 μm to about 50 μm, preferably about 10 μm; a center-to-center distance between two closest structures of about 0.5 μm to about 20 μm, preferably about 2 μm.

In an embodiment, the structures are of the same composition as the substrate. In an embodiment, the structures are an electrically insulating material, such as glass, polymer, oxide, or a combination thereof.

In an embodiment, a top portion of the structures is rounded or tapered. The structures may be rounded or tapered by any suitable method such as isotropic etch. The rounded or tapered top portion can enhance light coupling to the structures.

In an embodiment, a first junction is conformally disposed on the structures and a second junction is conformally disposed on the first junction. The first and second junctions may be selected from a p-i-n junction, a p-n junction, and a heterojunction. More junctions (e.g., 3^{rd} junction and 4^{th} junction in Table 1) may be conformally disposed on the second junction. In an embodiment, each of these junctions has a thickness of about 5 nm to about 100 nm, preferably about 20 nm.

In an embodiment, an electrically conductive layer may be disposed between the structures and the first junction. In an embodiment, this electrically conductive layer is coextensive with the entire interface between the first electrically conductive layer and the structures. This electrically conductive layer may have a thickness of about 2 nm to about 100 nm, preferably about 10 nm. This electrically conductive layer may be transparent, semitransparent or opaque.

In an embodiment, a transparent electrically conductive layer may be disposed between each pair of neighboring junctions. In an embodiment, the transparent electrically conductive layer is coextensive with the entire interface between a pair of neighboring junctions. This transparent electrically conductive layer may have a thickness of about 2 nm to about 100 nm, preferably about 10 nm. This transparent electrically conductive layer preferably has a transmittance of at least 90% for visible light. This transparent electrically conductive layer preferably forms an Ohmic contact with the pair of neighboring junctions. In an embodiment, this transparent electrically conductive layer comprises any suitable material such as ITO (indium tin oxide), AZO (aluminum doped zinc oxide), ZIO (zinc indium oxide), ZTO (zinc tin oxide), etc. This transparent electrically conductive layer connects the pair of neighboring junctions in series. The transparent electrically conductive layer preferably is effective to prevent diffusion between the neighboring junctions.

In an embodiment, one of the junctions comprises a heavily doped (p+) semiconductor material layer, a lightly doped (n−) semiconductor material layer, and a heavily doped (n+) semiconductor material layer. The p+ layer, the n− layer and the n+ layer form a p-n junction or heterojunction. The p+ layer, the n− layer and the n+ layer may be different semiconductor materials or the same semiconductor materials. The p+ layer, the n− layer and the n+ layer may be single crystalline, polycrystalline or amorphous.

In an embodiment, one of the junctions comprises a heavily doped (p+) semiconductor material layer, a lightly doped (p−) semiconductor material layer, and a heavily doped (n+) semiconductor material layer. The p+ layer, the p− layer and the n+ layer form a p-n junction or heterojunction. The p+ layer, the p− layer and the n+ layer may be different semiconductor materials or the same semiconductor materials. The p+ layer, the p− layer and the n+ layer may be single crystalline, polycrystalline or amorphous.

In an embodiment, one of the junctions comprises a heavily doped p type (p+) semiconductor material layer, an intrinsic (i) semiconductor layer and a heavily doped n type (n+) semiconductor material layer. The p+ layer, i layer, and the n+ layer form a p-i-n junction. The p+ layer, i layer, and the n+ layer may be single crystalline, polycrystalline (interchangeably referred to as “multicrystalline”), microcrystalline (“μc”) (interchangeably referred to as “nanocrystalline” or “nc”) or amorphous. In an embodiment, the junctions comprise one or more semiconductor materials selected from a group consisting of silicon, germanium, group III-V compound materials, group II-VI compound materials, and quaternary materials.

Nanocrystalline semiconductor, also known as microcrystalline semiconductor, is a form of porous semiconductor. It is an allotropic form of semiconductor with paracrystalline structure—is similar to amorphous semiconductor, in that it has an amorphous phase. Nanocrystalline semiconductor differs from amorphous semiconductor in that nanocrystalline semiconductor has small crystalline grains within the amorphous phase. This is in contrast to polycrystalline semiconductor (e.g., poly-Si) which consists solely of crystalline grains, separated by grain boundaries.

In an embodiment, the band gap of an inner junction (i.e., a junction closer to the structures) is smaller than the band gap of an outer junction (i.e., a junction farther from the structures).

Table 1 shows exemplary materials and combinations of the junctions.

| | | | | 4^{th} junction |
|---|---|---|---|---|
| | 1^{st} junction | | | (conformally |
| | (conformally | 2^{nd} junction | 3^{rd} junction | disposed on |
| | disposed on | (conformally | (conformally | the 3^{rd} |
| | and closest | disposed | disposed | junction and |
| | to the | on the | on the | farthest from |
| | structures) | 1^{st} junction) | 2^{nd} junction) | the structures) |
| Two | μc Si p-i-n | amorphous Si | none | none |
| junctions | junction or | (a-Si) p-i-n | | |
| on the | μc Ge p-i-n | junction | | |
| structures | junction or | | | |
| | poly-Si p-i-n | | | |
| | junction | | | |
| Three | μc Si p-i-n | amorphous | a-Si p-i-n | none |
| junctions | junction or | SiGe | junction or | |
| on the | μc Ge p-i-n | (a-SiGe) p-i-n | amorphous | |
| structures | junction or | junction | SiC | |
| | poly-Si p-i-n | | (a-SiC) p-i-n | |
| | junction | | junction | |
| Four | μc Ge p-i-n | μc Si p-i-n | a-SiGe p-i-n | a-Si p-i-n |
| junctions | junction | junction | junction or | junction or |
| on the | | | a-Si p-i-n | a-SiC p-i-n |
| structures | | | junction | junction |

In an embodiment, a cladding layer may be disposed conformally on the outermost junction (i.e., the junction that is among those junctions conformally disposed on the structures and is not between another junction and the structures). A transparent electrically conductive layer may be disposed between the outermost junction and the cladding layer.

The cladding layer is substantially transparent to visible light with a transmittance of at least 50%. The cladding layer may be made of an electrically conductive material or an electrically insulating material. In an embodiment, the cladding layer is a transparent conductive oxide. In an embodiment, the cladding layer is a material selected from a group consisting of indium tin oxide, aluminum doped zinc oxide, zinc indium oxide, and zinc tin oxide. In an embodiment, the cladding layer is a material selected from a group consisting of Si₃N₄, Al₂O₃, and HfO₂. In an embodiment, the cladding layer has a refractive index of about 2. In an embodiment, the cladding layer has a refractive index lower than that of any junctions between the cladding layer and the structures. In an embodiment, the cladding layer has a thickness from about 10 nm to about 500 nm, preferably about 200 nm. In an embodiment, the cladding layer is configured as an electrode of the photovoltaic device.

According to an embodiment, a reflective layer is disposed in a plurality of recesses between the structures and the reflective layer is above the junctions. The reflective layer may be a material selected from a group consisting of ZnO, Ni, Pt, Al, Au, Ag, Pd, Cr, Cu, Ti, and a combination thereof. The reflective layer is preferably an electrically conductive material such as a metal. The reflective layer preferably has a reflectance (i.e., the fraction of incident electromagnetic power that is reflected) of at least 50% for visible light (i.e., light have a wavelength from 390 to 750 nm) of any wavelength. The reflective layer has a thickness of at least 5 nm, preferably from about 20 nm to about 500 nm (e.g., about 200 nm). The reflective layer in the plurality of recesses is preferably connected. The reflective layer is functional to reflect light incident thereon to the structures so that the light is absorbed by the structures; and/or the reflective layer is functional as an electrode of the photovoltaic device. The reflective layer is preferably non-planar. The term “electrode” as used herein means a conductor used to establish electrical contact with the photovoltaic device.

According to an embodiment, a metal layer is disposed in a plurality of recesses between the structures, and the metal layer is between the junctions and the structures. The metal layer may be a material selected from a group consisting of Ni, Pt, AI, Au, Ag, Pd, Cr, Cu, Ti, and a combination thereof. The metal layer has a thickness of at least 5 nm, preferably from about 20 nm to about 500 nm (e.g., about 200 nm). The metal layer in the plurality of recesses is preferably connected. The metal layer is preferably planar. The metal layer is functional as an electrode of the photovoltaic device.

In an embodiment, space between the structures may be filled with a filler material such as a polymer. The filler material preferably is transparent and/or has a low refractive index. In an embodiment, a top surface of the filler material comprises one or more microlenses configured to concentrate incident light on the photovoltaic device onto the structures.

In an embodiment, a method of making the photovoltaic device comprises: generating a pattern of openings in a resist layer using a lithography technique, wherein locations and shapes of the openings correspond to location and shapes of the structures; forming the structures and regions therebetween by etching the substrate; depositing the reflective layer to the bottom wall. A resist layer as used herein means a thin layer used to transfer a pattern to the substrate, which the resist layer is deposited upon. A resist layer can be patterned via lithography to form a (sub)micrometer-scale, temporary mask that protects selected areas of the underlying substrate during subsequent processing steps. The resist is generally proprietary mixtures of a polymer or its precursor and other small molecules (e.g. photoacid generators) that have been specially formulated for a given lithography technology. Resists used during photolithography are called photoresists. Resists used during e-beam lithography are called e-beam resists. A lithography technique can be photolithography, e-beam lithography, holographic lithography. Photolithography is a process used in microfabrication to selectively remove parts of a thin film or the bulk of a substrate. It uses light to transfer a geometric pattern from a photo mask to a light-sensitive chemical photo resist, or simply “resist,” on the substrate. A series of chemical treatments then engraves the exposure pattern into the material underneath the photo resist. In complex integrated circuits, for example a modern CMOS, a wafer will go through the photolithographic cycle up to 50 times. E-beam lithography is the practice of scanning a beam of electrons in a patterned fashion across a surface covered with a film (called the resist), (“exposing” the resist) and of selectively removing either exposed or non-exposed regions of the resist (“developing”). The purpose, as with photolithography, is to create very small structures in the resist that can subsequently be transferred to the substrate material, often by etching. It was developed for manufacturing integrated circuits, and is also used for creating nanotechnology artifacts.

In an embodiment, the structures and regions therebetween are formed by deep etch followed by isotropic etch. A deep etch is a highly anisotropic etch process used to create deep, steep-sided holes and trenches in wafers, with aspect ratios of often 20:1 or more. An exemplary deep etch is the Bosch process. The Bosch process, also known as pulsed or time-multiplexed etching, alternates repeatedly between two modes to achieve nearly vertical structures: 1. a standard, nearly isotropic plasma etch, wherein the plasma contains some ions, which attack the wafer from a nearly vertical direction (For silicon, this often uses sulfur hexafluoride (SF₆)); 2. deposition of a chemically inert passivation layer (for instance, C₄F₈ source gas yields a substance similar to Teflon). Each phase lasts for several seconds. The passivation layer protects the entire substrate from further chemical attack and prevents further etching. However, during the etching phase, the directional ions that bombard the substrate attack the passivation layer at the bottom of the trench (but not along the sides). They collide with it and sputter it off, exposing the substrate to the chemical etchant. These etch/deposit steps are repeated many times over resulting in a large number of very small isotropic etch steps taking place only at the bottom of the etched pits. To etch through a 0.5 mm silicon wafer, for example, 100-1000 etch/deposit steps are needed. The two-phase process causes the sidewalk to undulate with an amplitude of about 100-500 nm. The cycle time can be adjusted: short cycles yield smoother walls, and long cycles yield a higher etch rate. Isotropic etch is non-directional removal of material from a substrate via a chemical process using an etchant substance. The etchant may be a corrosive liquid or a chemically active ionized gas, known as a plasma.

In an embodiment, a method of converting light to electricity comprises: exposing the photovoltaic device to light; drawing an electrical current from the photovoltaic device. The electrical current can be drawn from the wavelength-selective layer.

In an embodiment, a photo detector comprises the photovoltaic device, wherein the photo detector is configured to output an electrical signal when exposed to light.

In an embodiment, a method of detecting light comprises exposing the photovoltaic device to light; measuring an electrical signal from the photovoltaic device. The electrical signal can be an electrical current, an electrical voltage, an electrical conductance and/or an electrical resistance. A bias voltage is applied to the structures in the photovoltaic device.

In an embodiment, photovoltaic devices produce direct current electricity from sun light, which can be used to power equipment or to recharge a battery. A practical application of photovoltaics was to power orbiting satellites and other spacecraft, but today the majority of photovoltaic modules are used for grid connected power generation. In this case an inverter is required to convert the DC to AC. There is a smaller market for off-grid power for remote dwellings, boats, recreational vehicles, electric cars, roadside emergency telephones, remote sensing, and cathodic protection of pipelines. In most photovoltaic applications the radiation is sunlight and for this reason the devices are known as solar cells. In the case of a p-n junction solar cell, illumination of the material results in the creation of an electric current as excited electrons and the remaining holes are swept in different directions by the built-in electric field of the depletion region. Solar cells are often electrically connected and encapsulated as a module. Photovoltaic modules often have a sheet of glass on the front (sun up) side, allowing light to pass while protecting the semiconductor wafers from the elements (rain, hail, etc.). Solar cells are also usually connected in series in modules, creating an additive voltage. Connecting cells in parallel will yield a higher current. Modules are then interconnected, in series or parallel, or both, to create an array with the desired peak DC voltage and current.

In an embodiment, the photovoltaic device can also be associated with buildings: either integrated into them, mounted on them or mounted nearby on the ground. The photovoltaic device can be retrofitted into existing buildings, usually mounted on top of the existing roof structure or on the existing walls. Alternatively, the photovoltaic device can be located separately from the building but connected by cable to supply power for the building. The photovoltaic device can be used as as a principal or ancillary source of electrical power. The photovoltaic device can be incorporated into the roof or walls of a building.

In an embodiment, the photovoltaic device can also be used for space applications such as in satellites, spacecrafts, space stations, etc. The photovoltaic device can be used as main or auxiliary power sources for land vehicles, marine vehicles (boats) and trains. Other applications include road signs, surveillance cameras, parking meters, personal mobile electronics (e.g., cell phones, smart phones, laptop computers, personal media players).

### EXAMPLES

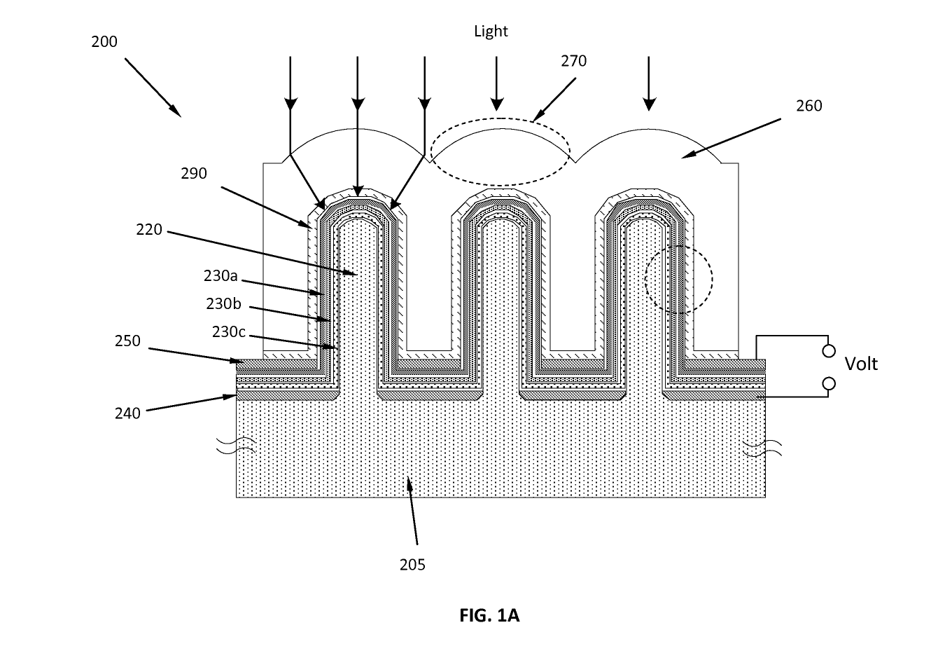

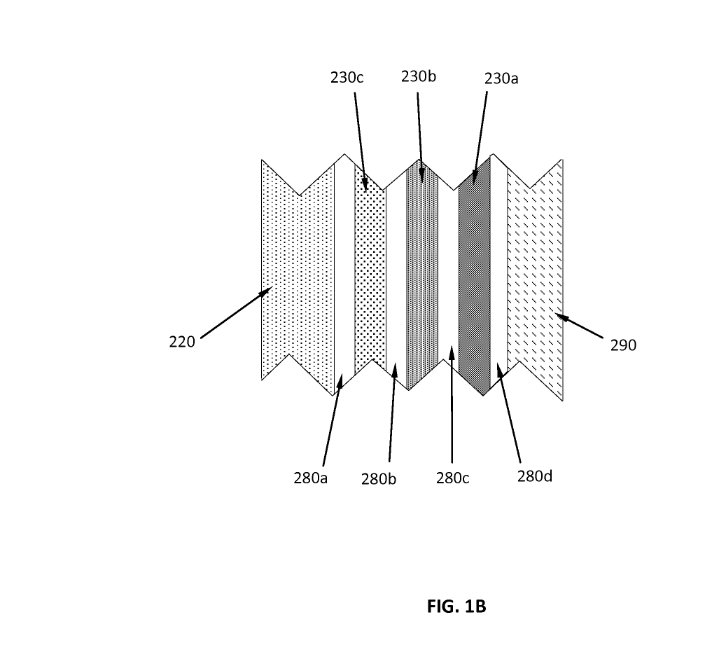

FIG. 1A shows a schematic cross-section of a photovoltaic device 200, according to an embodiment. FIG. 1B shows details of the device 200 in the dotted circle. The photovoltaic device 200 comprises a substrate 205, one or more structures 220 essentially perpendicular to the substrate 205. A first junction 230c is conformally disposed on the structures 220. A transparent electrically conductive layer 280a is conformally disposed between the structures 220 and the first junction 230c. A second junction 230b is conformally disposed on the first junction 230c. A transparent electrically conductive layer 280b is conformally disposed between the second junction 230b and the first junction 230c. A third junction 230a is conformally disposed on the second junction 230b. A transparent electrically conductive layer 280c is conformally disposed between the third junction 230a and the second junction 230b. A cladding layer 290 is conformally disposed on the third junction 230a, which is the outermost junction in this example. A transparent electrically conductive layer 280d is disposed between the third junction 230a and the cladding layer 290. A reflective layer 250 is disposed in a plurality of recesses between the structures 220 and the reflective layer 250 is above the junctions 230a, 230b and 230c. The reflective layer 250 is functional to reflect light incident thereon to the structures 220 and is functional as an electrode of the photovoltaic device 200. A metal layer 240 is disposed in a plurality of recesses between the structures 220, and the metal layer 240 is between the first junction 230c and the structures 220. The metal layer 240 is functional as an electrode of the photovoltaic device 200. Space between the structures 220 is filled with a filler material 260. A top surface of the filler material 260 has a plurality of microlenses 270.

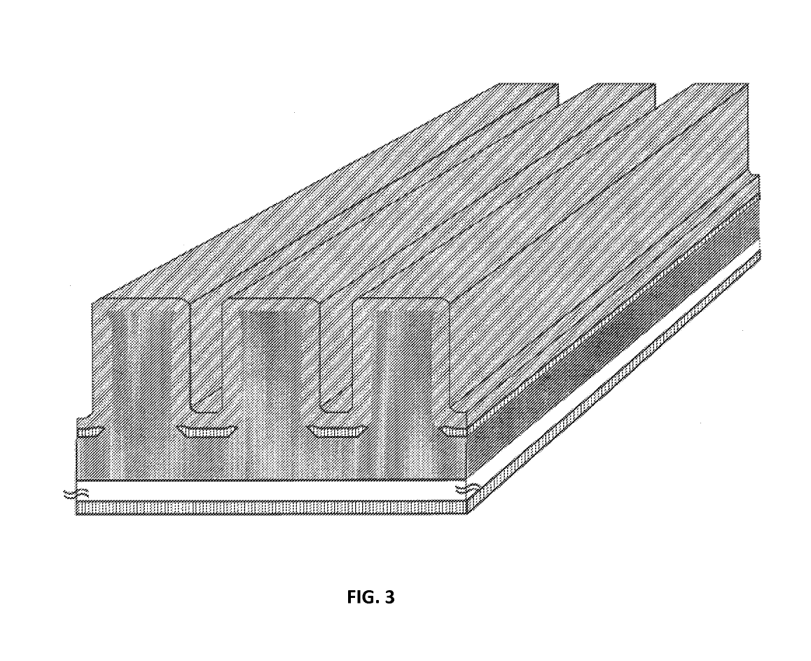

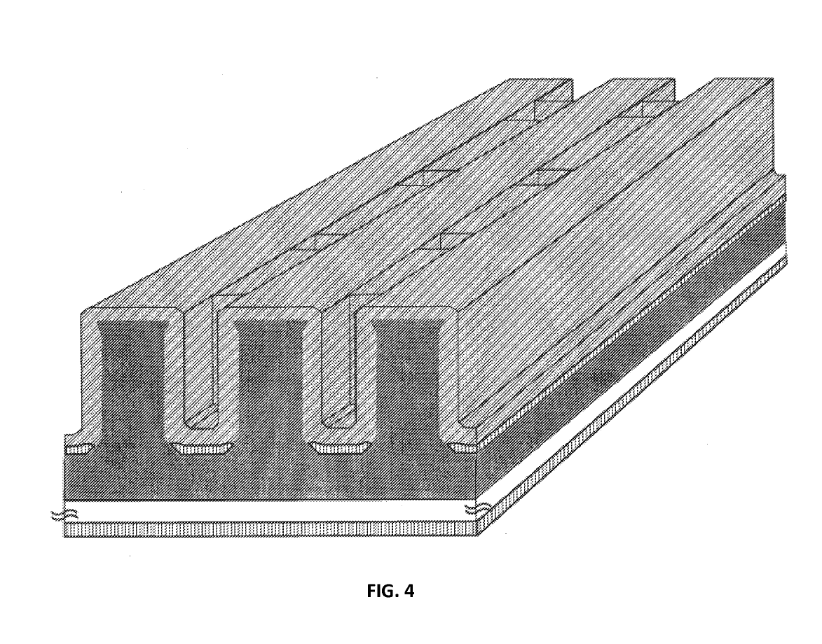

The structures 220 can have any cross-sectional shape. For example, the structures 220 can be cylinders or prisms with elliptical, circular, rectangular, polygonal cross-sections. The structures 220 can also be strips as shown in FIG. 3, or a mesh as shown in FIG. 4.

In one embodiment, the structures 220 are pillars arranged in an array, such as a rectangular array, a hexagonal array, a square array, concentric ring.

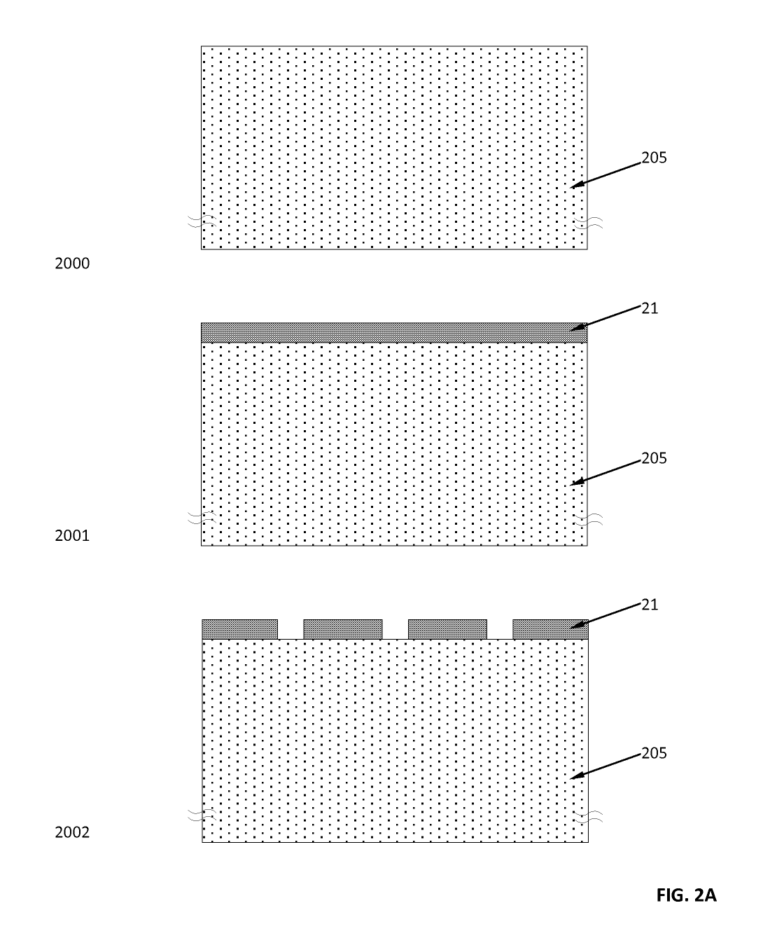

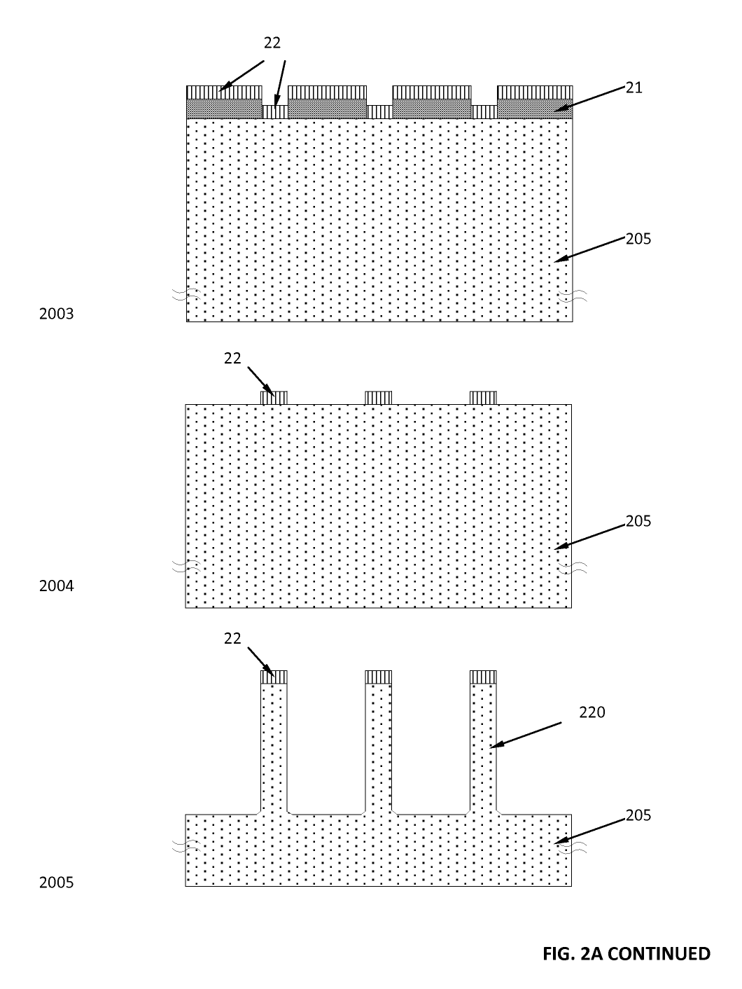

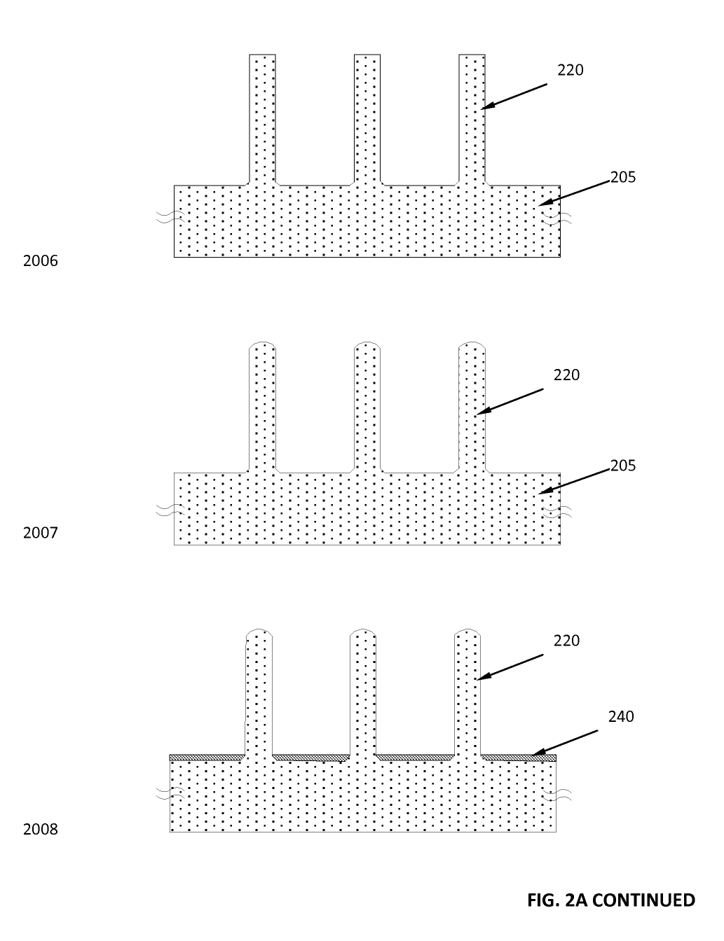

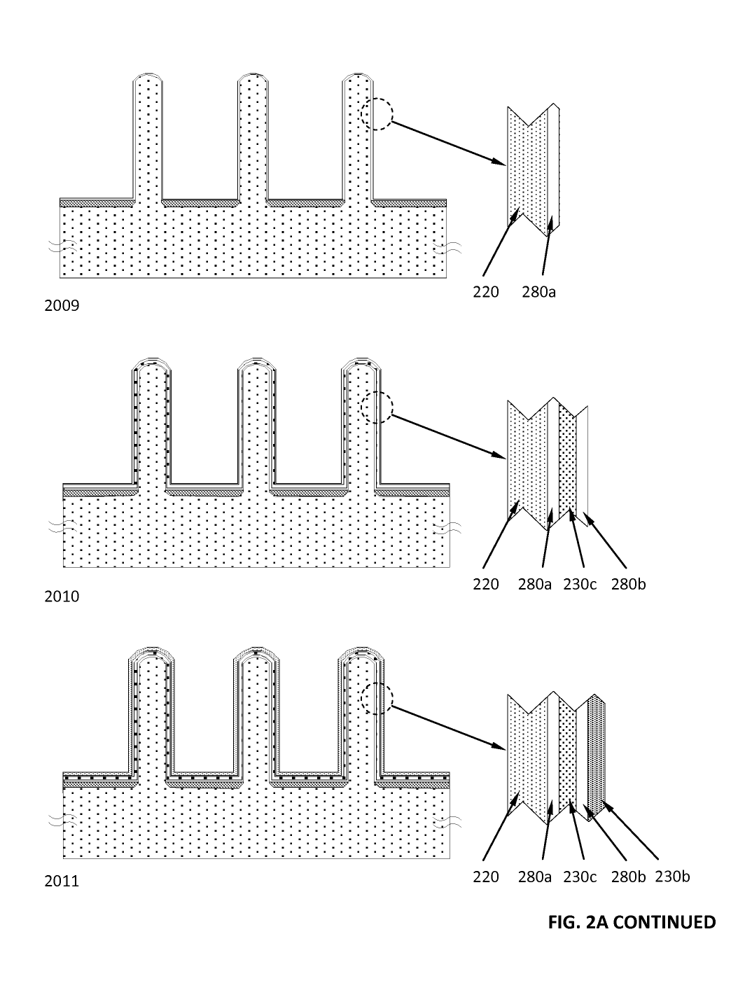

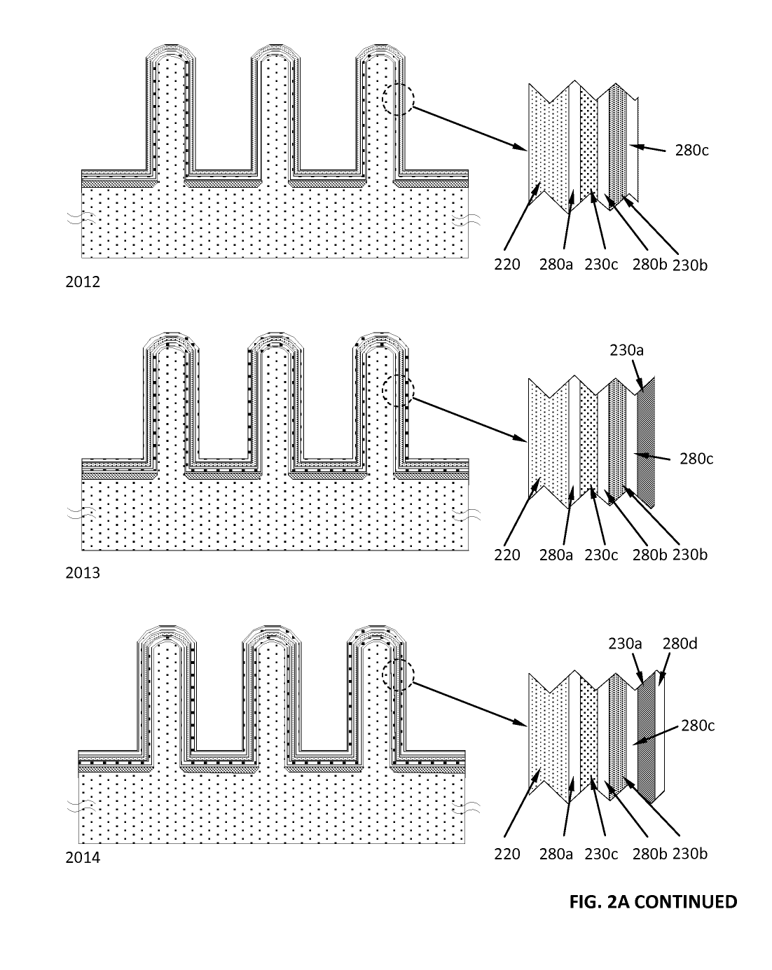

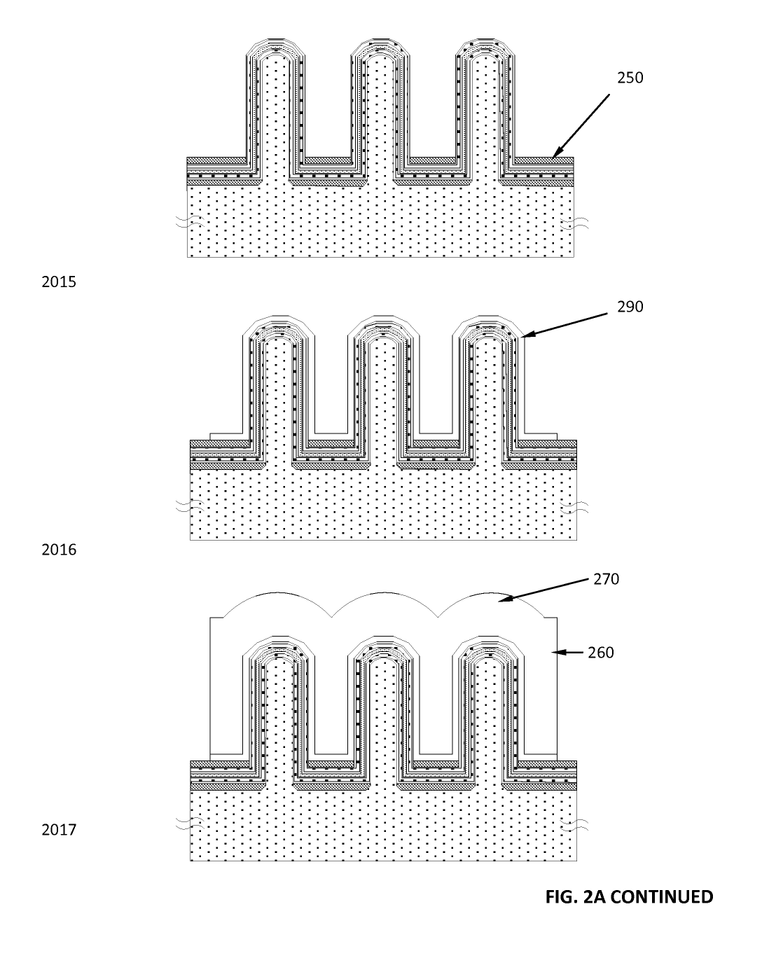

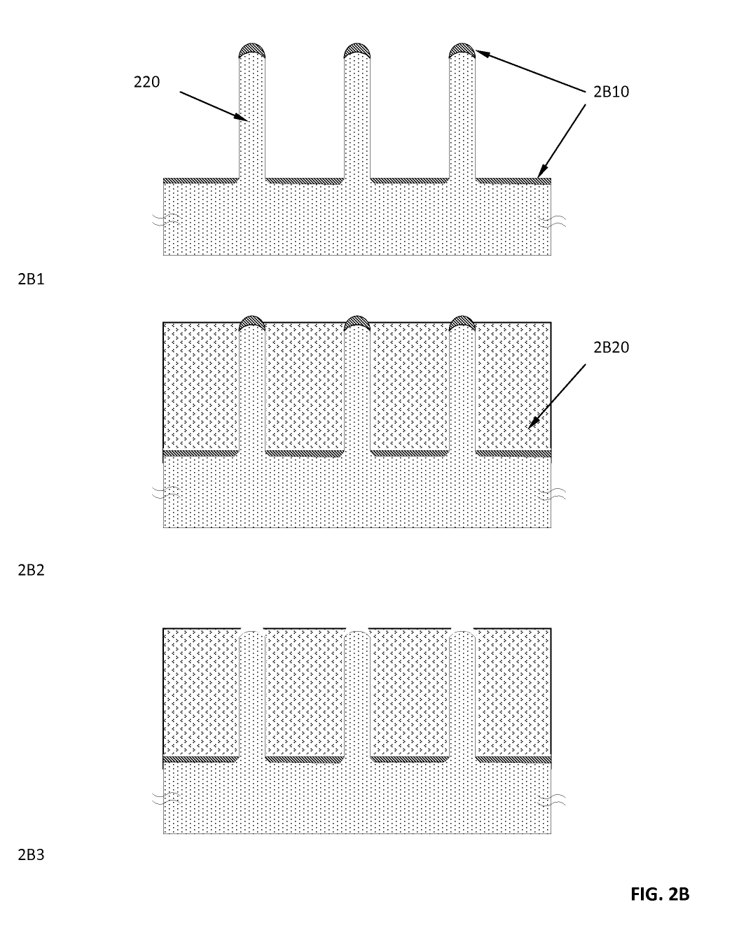

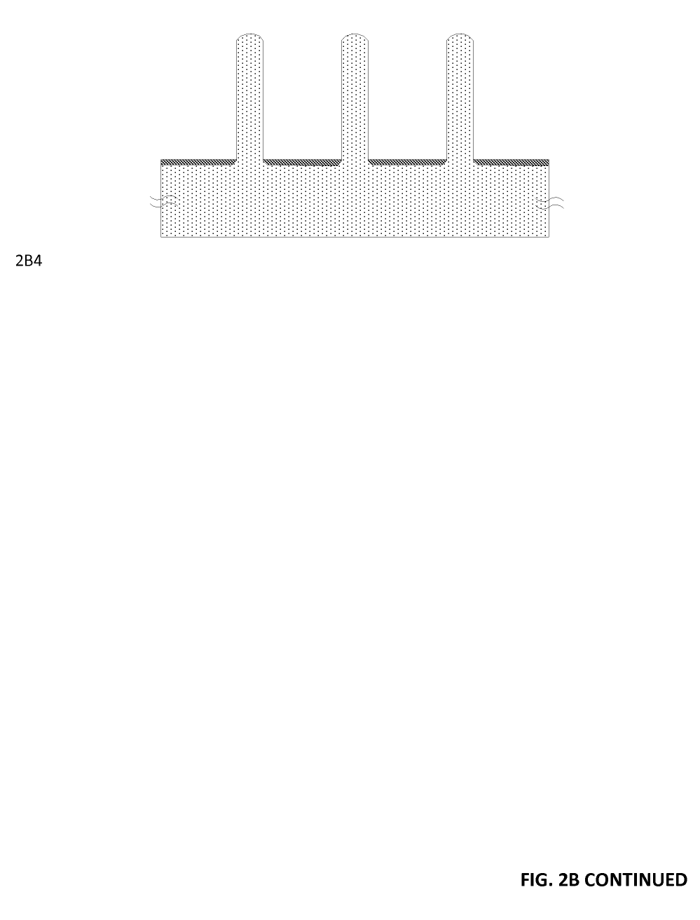

A method of making the photovoltaic device 200 as shown in FIG. 2A, according to an embodiment, comprises the following steps:

In step 2000, the substrate 205 is provided.

In step 2001, a resist layer 21 is applied to the substrate 205. The resist layer 21 can be applied by spin coating. The resist layer 21E can be a photo resist or an e-beam resist.

In step 2002, lithography is performed. The resist layer 21 now has a pattern of openings in which the substrate 205 is exposed. The resolution of the lithography is limited by the wavelength of the radiation used. Photolithography tools using deep ultraviolet (DUV) light with wavelengths of approximately 248 and 193 nm, allows minimum feature sizes down to about 50 nm. E-beam lithography tools using electron energy of 1 keV to 50 keV allows minimum feature sizes down to a few nanometers.

In step 2003, a mask layer 22 is deposited over the remaining portion of the resist layer 21 and the exposed portion of the substrate 205. The mask layer 22 can be deposited using any suitable method such as thermal evaporation, e-beam evaporation, sputtering. The mask layer 22 can be a metal such as Cr or Al, or a dielectric such as SiO_{2 or Si}₃N₄. The thickness of the mask layer 22 can be determined by a height of the structures 220 and etching selectivity (i.e., ratio of etching rates of the mask layer 22 and the substrate 205).

In step 2004, remainder of the resist layer 21 is lift off by a suitable solvent or ashed in a resist asher.

In step 2005, the exposed portion of the substrate 205 is deep etched to a desired depth, to form the structures 220.

In step 2006, the mask layer 22 is removed by a suitable such as wet etching with suitable etchant, ion milling, sputtering.

In step 2007, a top portion of the structures 220 is rounded or tapered using a suitable technique such as dry etch or wet etch.

In step 2008, the metal layer 240 is deposited between the structures 220. This step may be carried out using the exemplary process shown in FIG. 2B.

In step 2009, the transparent electrically conductive layer 280a is conformally (i.e., isotropically) deposited on the structures 220 and the metal layer 240. The transparent electrically conductive layer 280a can be deposited by a suitable technique such as plating, chemical vapor deposition or atomic layer deposition.

In step 2010, the junction 230c is conformally deposited on the transparent electrically conductive layer 280a; and the transparent electrically conductive layer 280b is conformally deposited on the junction 230c.

In step 2011, the junction 230b is conformally deposited on the transparent electrically conductive layer 280b.

In step 2012, the transparent electrically conductive layer 280c is conformally deposited on the junction 230b.

In step 2013, the junction 230a is conformally deposited on the transparent electrically conductive layer 280c.

In step 2014, the transparent electrically conductive layer 280d is conformally deposited on the junction 230a.

In step 2015, the reflective layer 250 is deposited between the structures 220, and above the junctions 230a, 230b and 230c. This step may be carried out using the exemplary process shown in FIG. 2B.

In step 2016, the cladding layer 290 is conformally deposited on the transparent electrically conductive layer 280d and the reflective layer 250.

In step 2017, the filler material 260 is deposited in space between the structures 220 and microlenses 270 are formed on the top surface of the filler material 260.

FIG. 2B shows an exemplary process of depositing a material 2B10 only between the structures 220 but not on top of the structures 220.

In step 2B1, the material 2B10 is anisotropically deposited on the top of the structures 220 and between the structures 220.

In step 2B2, a sacrificial material 2B20 such as a resist is deposited such that the material 2B10 on the top of the structures 220 is exposed and the material 2B10 between the structures 220 is not exposed. This can be achieved by controlling the amount of sacrificial material 2B20 or by removing some of the sacrificial material 2B20.

In step 2B3, the material 2B10 on the top of the structures 220 is removed by any suitable method such as dissolution is a solvent, or etching.

In step 2B4, the sacrificial material 2B20 is removed.

A method of converting light to electricity comprises: exposing the photovoltaic device 200 to light; absorbing the light and converting the light to electricity using the structure 220; drawing an electrical current from the photovoltaic device 200. As shown in FIGS. 1A and 1B, the electrical current can be drawn from the metal layer 240 and the reflective layer 250.

A photo detector according to an embodiment comprises the photovoltaic device 200, wherein the photo detector is configured to output an electrical signal when exposed to light.

A method of detecting light comprises: exposing the photovoltaic device 200 to light; measuring an electrical signal from the photovoltaic device 200. The electrical signal can be an electrical current, an electrical voltage, an electrical conductance and/or an electrical resistance. A bias voltage can be applied to the structures 220 in the photovoltaic device 200 when measuring the electrical signal.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A photovoltaic device operable to convert light to electricity, comprising a substrate, one or more structures essentially perpendicular to the substrate, and a reflective layer disposed on the substrate, and one or more junctions conformally disposed on the one or more structures.

2. The photovoltaic device of claim 1, wherein the photovoltaic device comprises at least two junctions conformally disposed on the one or more structures.

3. The photovoltaic device of claim 1, wherein reflective layer is non-planar.

4. The photovoltaic device of claim 2, wherein the two or more junctions are electrically connected in series.

5. The photovoltaic device of claim 1, wherein the substrate is an electrically insulating material.

6. The photovoltaic device of claim 1, wherein the substrate comprises glass, polymer or a combination thereof.

7. The photovoltaic device of claim 1, wherein the substrate is flexible.

8. The photovoltaic device of claim 1, wherein the substrate is transparent.

9. The photovoltaic device of claim 1, wherein the one or more structures have the same composition as the substrate.

10. The photovoltaic device of claim 1, wherein the structures are cylinders or prisms with a cross-section selected from a group consisting of elliptical, circular, rectangular, and polygonal cross-sections, strips, or a mesh.

11. The photovoltaic device of claim 1, wherein the structures are cylinders with diameters from about 0.2 μm to about 10 μm, heights from about 2 μm to about 50 μm, a center-to-center distance between two closest pillars of about 0.5 μm to about 20 μm.

12. The photovoltaic device of claim 1, wherein a top portion of the structures is rounded or tapered.

13. The photovoltaic device of claim 1, wherein the one or more junctions are selected from a group consisting of a p-i-n junction, a p-n junction, and a heterojunction.

14. The photovoltaic device of claim 1, wherein the one or more junctions comprises a heavily doped p type semiconductor material layer and a heavily doped n type semiconductor material layer, and optionally an intrinsic semiconductor layer sandwiched between the heavily doped p type semiconductor material layer and the heavily doped n type semiconductor material layer.

15. The photovoltaic device of claim 1, wherein the one or more junctions comprises a microcrystalline semiconductor material.

16. The photovoltaic device of claim 1, wherein the one or more junctions comprises a semiconductor material selected from a group consisting of silicon, germanium, group III-V compound materials, group II-VI compound materials, and quaternary materials.

17. The photovoltaic device of claim 2, wherein a first junction of the two or more junctions has a smaller bandgap than a second junction of the two or more junctions, where in the first junction is closer to the structures than the second junction.

18. The photovoltaic device of claim 2, further comprising at least one an electrically conductive layer disposed between the structures and one of the two or more junctions, and/or layer disposed between a pair of neighboring junctions of the two or more junctions.

19. The photovoltaic device of claim 1, further comprising a cladding layer.

20. The photovoltaic device of claim 19, wherein the cladding layer is substantially transparent to visible light with a transmittance of at least 50%; the cladding layer is made of an electrically conductive material; the cladding layer is a transparent conductive oxide; the cladding layer is a material selected from a group consisting of indium tin oxide, aluminum doped zinc oxide, zinc indium oxide, Si₃N₄, Al₂O₃, and HfO₂, and zinc tin oxide; the cladding layer has a thickness from 10 nm to 500 nm; and/or the cladding layer is configured as an electrode of the photovoltaic device.

21. The photovoltaic device of claim 1, wherein the reflective layer is an electrically conductive material; the reflective layer has a reflectance of at least 50% for visible light; the reflective layer has a thickness from about 20 nm to about 500 nm; and/or the reflective layer is an electrode of the photovoltaic device.

22. A method of making the photovoltaic device of claim 1, comprising:
generating a pattern of openings in a resist layer using a lithography technique, wherein locations and shapes of the openings correspond to location and shapes of the structures;
forming the structures by etching the substrate;
depositing the reflective layer to the substrate.

23. The method of claim 22, further comprising tapering or rounding a top portion of the structures.

24. The method of claim 22, wherein the structures are formed by deep etch.

25. A method of converting light to electricity comprising:
exposing a photovoltaic device to light, wherein the photovoltaic device comprises a substrate, one or more structures essentially perpendicular to the substrate, and a reflective layer disposed on the substrate, and two or more junctions conformally disposed on the one or more structures;
drawing an electrical current from the photovoltaic device.

26. A photo detector comprising the photovoltaic device of claim 1, wherein the photo detector is configured to output an electrical signal when exposed to light.

27. A method of detecting light comprises:
exposing the photovoltaic device of claim 1 to light;
measuring an electrical signal from the photovoltaic device.

28. The method of claim 27, wherein the electrical signal is an electrical current, an electrical voltage, an electrical conductance and/or an electrical resistance.

29. The method of claim 27, wherein a bias voltage is applied to the structures in the photovoltaic device.
